(19) United States
(12) Patent Application Publication
(10) Pub. No.: US 2005/0083771 A1
(43) Pub. Date: Apr. 21, 2005

(54) Plasma display panel driving method and plasma display device

(76) Inventors: Myoung-Kwan Kim, Suwon-si (KR); Nam-Sung Jung, Suwon-si (KR)

Correspondence Address: McGuire Woods LLP, Suite 1800, 1750 Tysons Boulevard, McLean, VA, 22102, US

(21) Appl. No.: 10/965,266

(22) Filed: Oct. 15, 2004

(30) Foreign Application Priority Data
Oct. 16, 2003 (KR) 10-2003-0072352

(51) Int. Cl. G11C 5/00

(52) U.S. Cl. 365/232

(57) ABSTRACT

A PDP driving method for solving misfiring in an address period may include applying, in the address period, an address voltage through a hard switching operation while a low scan voltage is applied to a first scan electrode from among scan electrodes. The address voltage may be applied through an operation by an address energy recovery circuit while the low scan voltage is applied to other scan electrodes. Therefore, since the address voltage is applied through the hard switching operation to generate strong light when the first scan electrode line is scanned in the address period, a discharge success rate may increase, and the discharge success rates of subsequent lines can be increased.

### CROSS REFERENCE TO RELATED APPLICATION

This application claims priority to and the benefit of Korea Patent Application No. 2003-72352 filed on Oct. 16, 2003, the entirety of which is incorporated herein by reference.

### BACKGROUND OF THE INVENTION

1. Field of the Invention

The present invention relates to a plasma display panel (PDP) driving method. More specifically, the present invention relates to a PDP driving method for solving a misfiring problem in an address period.

2. Description of the Related Art

A PDP is a flat display for showing characters or images using plasma generated by gas discharge. PDPs can include a large number of pixels (sometimes more than several million) in a matrix format, in which the number of pixels are determined by the size of the PDP.

FIG. 1 shows a partial perspective view of the PDP, and FIG. 2 schematically shows an electrode arrangement of a PDP.

As shown in FIG. 1, the PDP includes glass substrates 1 and 6 facing each other with a predetermined gap therebetween. Scan electrodes 4 and sustain electrodes 5 in pairs may be formed in parallel on the glass substrate 1. The scan electrodes 4 and the sustain electrodes may be covered with a dielectric layer 2 and a protection film 3. A plurality of address electrodes 8 may be formed on the glass substrate 6, and the address electrodes 8 may be covered with an insulator layer 7. Barrier ribs 9 may be formed on the insulator layer 7 between the address electrodes 8. Phosphors 10 may be formed on the surface of the insulator layer 7 and between the barrier ribs 9. The glass substrates 1 and 6 may be provided facing each other with discharge spaces between the glass substrates 1 and 6. Thus, the scan electrodes and the sustain electrodes 5 can cross the address electrodes 8. A discharge space 11 between an address electrode 8 and a crossing part of a pair of a scan electrode 4 and a sustain electrode 5 may form a discharge cell 12.

As shown in FIG. 2, the electrodes of the PDP may have an n×m matrix format. The address electrodes A₁ to Aₘ may be arranged in the column direction. N scan electrodes Y₁ to Yₙ and n sustain electrodes X₁ to Xₙ may be arranged in pairs in the row direction.

A subfield in the PDP driving method may include a reset period, an address period, a sustain period, and an erase period (waveforms within a subfield will be described for ease of description).

In the reset period, states of respective cells may be reset to address the cells fluently. In the address period (or a scan period or a write period), cells that are turned on and turned off on the panel may be selected, and wall charges may be accumulated at the turned-on cells (addressed cells). In the sustain period, a discharge for displaying actual images on the addressed cells may be performed. In the erase period, the wall charges on the cells may be reduced, and the sustain discharge may be terminated.

FIG. 3 shows a conventional PDP driving method.

As shown, all the discharge cells may be discharged by a ramp voltage that rises in the reset period. Thus, a large amount of negative charges may be charged at the scan electrode Y and a large amount of positive charges may be charged at the address electrode A.

Next, a ramp voltage that falls to the potential of the ground level may be applied to the scan electrode Y. In this instance, the wall charges formed at the discharge cells may be erased by the rising ramp voltage, thereby erasing the wall charges accumulated at the discharge cells.

In the address (or the scan) period, a positive voltage of Va may be applied to the address electrode A, and a ground level voltage GND may be applied to the scan electrode Y to perform an address discharge. A sustain discharge voltage of Vs may be alternately applied to the scan electrode Y and the sustain electrode X in the sustain period. Thus, images may be displayed on the cells selected in the address period.

In this instance, a positive voltage of Va may be applied to the address electrode A to select a desired cell in the address period when the ground level voltage GND is alternately applied to the scan electrodes Y. It may be applied from the first scan electrode Y1 to the n^{th} scan electrode Yn. Here, the waveform applied to the address electrode A may have a waveform of an LC resonance format in the rising period and the falling period in the same manner of the magnified waveform applied to the address electrode as shown in FIG. 3 when power consumption is controlled by using an address energy recovery circuit (AERC).

However, a misfiring may frequently occur when the address voltage of Va is applied using an AERC in the address period. The application of the address voltage of Va using an AERC may increase the voltage rise time to the voltage of Va and the voltage fall time from the voltage of Va to the ground voltage GND because of the LC resonance. Also, the time for maintaining the address voltage of Va using an AERC may be shorter than the time for applying the address voltage of Va through a hard switching operation (an operation for applying the address voltage of Va without using an AERC.) That is, in the case of applying the address voltage of Va through an AERC, the address discharge time caused by applying the voltage of Va may be delayed by more than the time by the hard switching operation. Likewise, the time for maintaining the Va pulse may be short, and the Va pulse width may not be long enough for a discharge delay. Thus, the probability of generating misfire may substantially increase.

In detail, insufficiently charged wall charges may be generated. This may be because the optical waveform caused by using the AERC may be weaker than the optical waveform caused by using the hard switching operation.

When the address voltage of Va is applied to the first line of the scan lines of the PDP by using the AERC, the width of the Va pulse may be shortened, and the misfiring may be generated. Hence, the misfiring may occur in the case of scanning the next scan line because the probability of generating a misfire at the next cell becomes higher when a misfiring occurs in an adjacent cell. This is because of the priming effect, in which the probability of discharge at a cell is increased when an adjacent cell is discharged. Therefore, the successful discharge rate of the first line influences the successful discharge rate of all lines.

### SUMMARY OF THE INVENTION

It is an advantage of the present invention to provide a PDP driving method for preventing address misfiring in an address period of the PDP.

One aspect of the present invention is a method for driving a PDP. The PDP may include a plurality of first and second electrodes formed in parallel on a first substrate, and a plurality of third electrodes crossing the first and second electrodes and formed on a second substrate. The adjacent first, second, and third electrodes may form a discharge cell. The method may include, in an address period, applying a first voltage to at least one of the first electrodes, and applying a second voltage having a first period to the third electrode while the first voltage is applied. It may also include applying the first voltage to the first electrodes except the at least one first electrode, and applying the second voltage having a period shorter than the first period to the third electrode while the first voltage is applied. The term voltage can include reference to a voltage waveform in addition to a static voltage level.

The time for applying the second voltage having the first period is shorter than the time for applying the second voltage having the second period.

The second voltage may not be applied by LC resonance of an energy recovery circuit, and the second voltage may be applied by LC resonance of the energy recovery circuit.

The first electrodes may be divided into a first group and a second group, and the first voltage may be sequentially applied to the first and second groups.

The at least one first electrode may be the first electrode of the first line.

In another aspect of the present invention may be a plasma display device. The device may include a first substrate, a plurality of first and second electrodes formed in parallel on the first substrate, and a second substrate facing the first substrate with a gap therebetween. It may also include a plurality of third electrodes on the second substrate crossing the first and second electrodes. Additionally, it may include a driving circuit for supplying a driving voltage to the first, second, and third electrodes so as to discharge a discharge cell formed by the first, second, and third electrodes. The driving circuit may apply a first voltage to at least one of the first electrodes during an address period. It may also apply a second voltage having a first period to the third electrode while the first voltage is applied. It may further apply the first voltage to the first electrodes except the at least one first electrode. Additionally, it may apply a second voltage having a second period shorter than the first period to the third electrode while the first voltage is applied.

### BRIEF DESCRIPTION OF THE DRAWINGS

FIG. 1 shows a partial perspective view of a general PDP.

FIG. 2 shows a general PDP electrode arrangement diagram.

FIG. 3 shows a conventional PDP driving waveform diagram.

FIG. 4 shows a PDP driving waveform diagram according to an exemplary embodiment of the present invention.

FIG. 5 shows a waveform of the address voltage and a corresponding optical waveform when the hard switching operation is performed without an operation by the AERC.

FIG. 6 shows a waveform of the address voltage applied to the address electrode through an operation by the AERC, and a corresponding optical waveform.

FIG. 7 shows a case of applying an address voltage to the first line of a first group and the first line of a second group through a hard switching operation in the dual scan driving method.

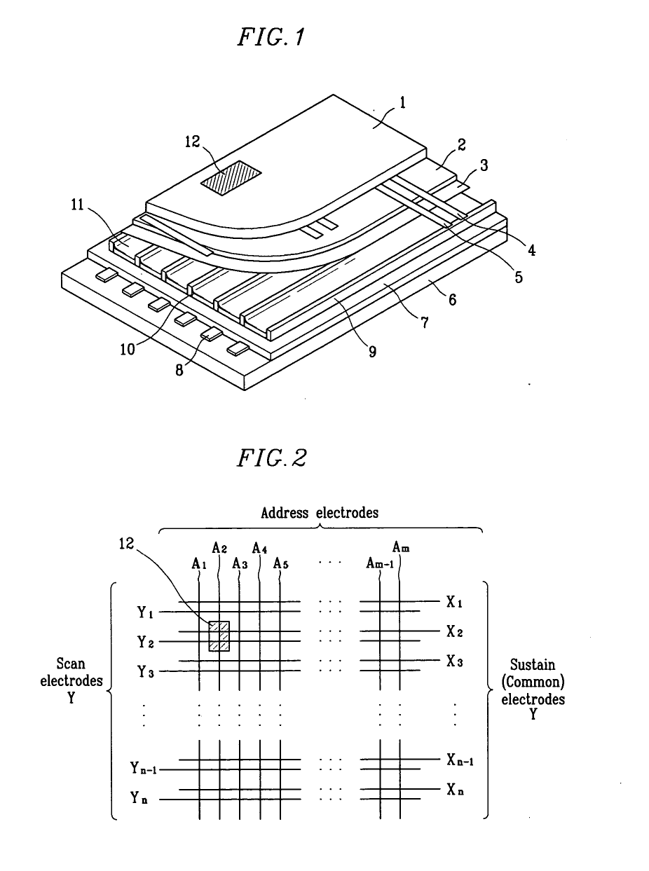

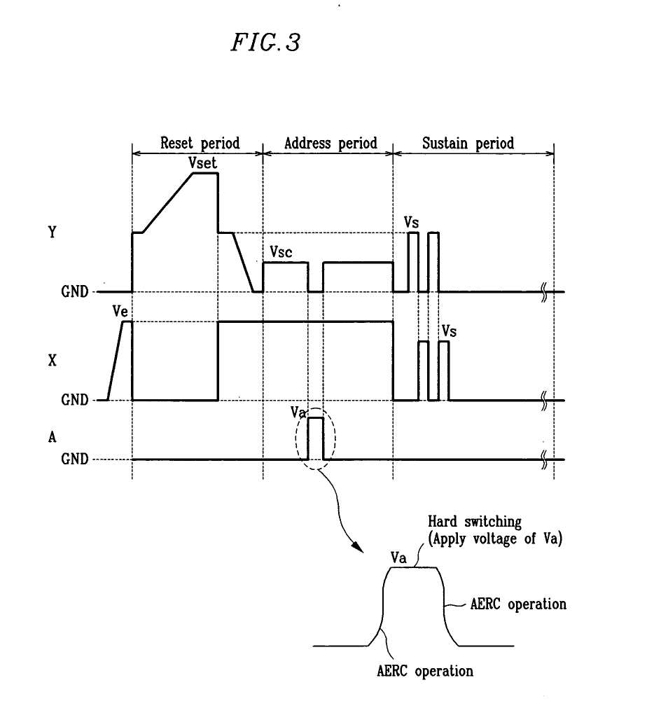

### DETAILED DESCRIPTION OF THE PREFERRED EMBODIMENTS

In the following detailed description, only the preferred embodiment of the invention has been shown and described, simply by way of illustration. As will be realized, the invention can be modified in various obvious respects, all without departing from the invention. Accordingly, the drawings and description are to be regarded as illustrative in nature, and not restrictive.

A PDP driving method according to an exemplary embodiment of the present invention will now be described. For ease of description, the PDP is driven in a single subfield, but the embodiment may be applied to all the subfields.

As shown in FIG. 4, the driving waveform may include a reset period, an address period, and a sustain period. The PDP may be coupled to a scan/sustain driving circuit (not illustrated) for applying a driving voltage to the scan electrode Y and the sustain electrode X, and an address driving circuit (not illustrated) for applying a driving voltage to the address electrode A.

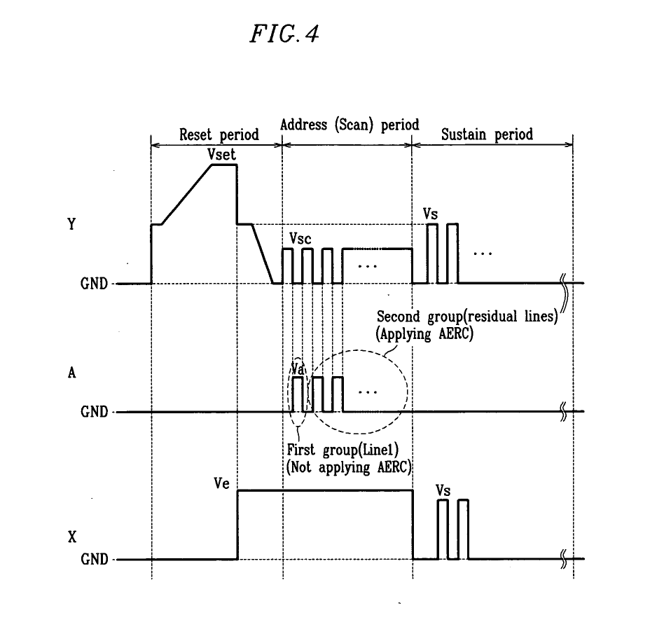

In the reset period as shown in FIG. 3, all the discharge cells may be discharged using a rising ramp voltage to charge a large amount of negative charges at the scan electrode Y and a large amount of positive charges at the address electrode A. Next, a falling ramp voltage applied to the scan electrode Y may be reduced to the ground voltage, and the wall charges formed at the discharge cells by the rising ramp voltage may be erased.

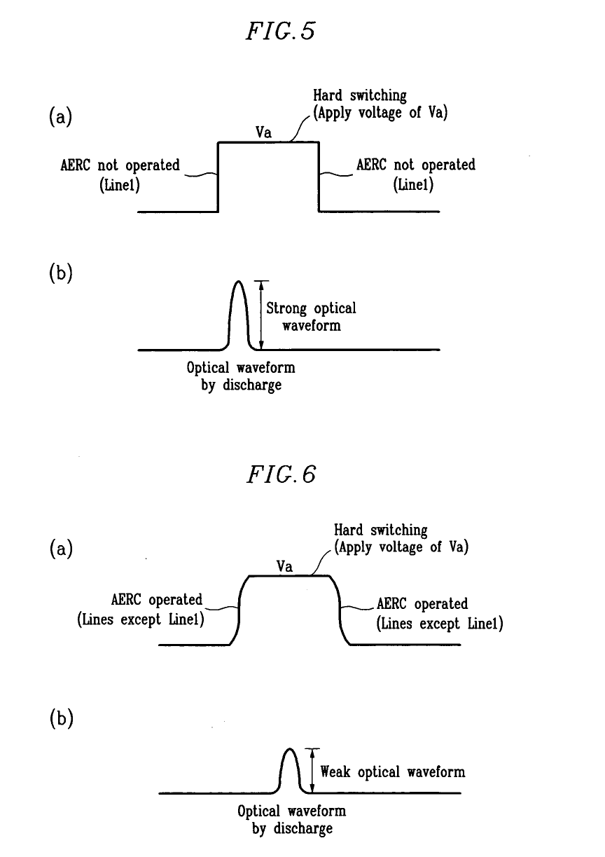

Next, when a low level ground voltage GROUND is applied to the scan electrode Y and a scan operation is performed in order to select a discharge cell to be displayed from among the discharge cells, the first line (e.g., the first line Line1 of from among the, for example, total 768 scan electrode lines) of the scan lines of the scan electrodes Y in the address period may apply the address voltage of Va (refer to FIG. 5A) to the address electrode A through the hard switching operation without using the AERC. The residual lines may apply the same (refer to FIG. 6A) to the address electrode A by using the AERC.

As to realizing the dual scan method, the waveform as shown in FIG. 5A may be applied to a first line (e.g., Line1 of the 768 lines) of a first group (e.g., Line1 to Line384 of the 768 lines) and the first line (e.g., Line385 of the 768 lines) of the second group (e.g., Line385 to Line768 of the 768 lines), and the waveform as shown in FIG. 6A is applied to the residual lines.

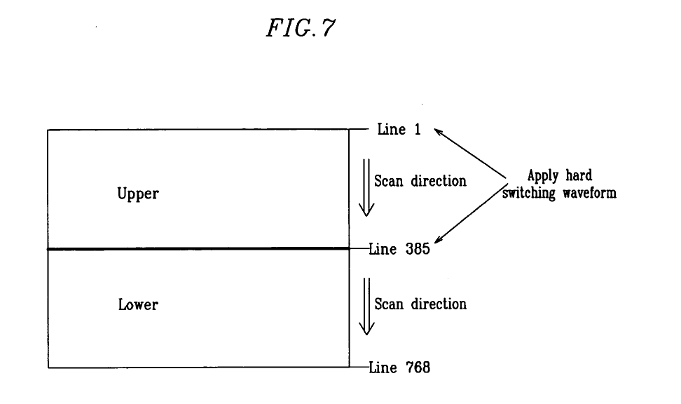

FIG. 7 shows a case of applying an address voltage to the first line of a first group and the first line of a second group through a hard switching operation in the dual scan driving method. When applying the address voltage to the first line of the first group and the first line of the second group through the hard switching operation in the same manner as FIG. 7, the problem of line misfiring on the first line of the second group because of misfiring that may occur on the first line may be solved.

By applying the address voltage of Va to the first line (or a front part line) by using the hard switching operation as shown in FIG. 5A, the address discharge start time may become earlier, the Va voltage pulse width may be lengthened, and hence, the successful address discharge rate may be increased and strong light may be formed by the hard switching operation as shown in FIG. 5B. By applying the address voltage of Va that uses the AERC of FIG. 6A to the residual lines (lines of the scan electrode Y except the first scan line), the address discharge start time may become late, the Va voltage pulse width may be shortened, weak light caused by the address discharge may be formed (refer to FIG. 6B), and a power recovery operation may be performed.

Since the start point of applying the address voltage of Va on the first line by the hard switching operation may be earlier than the start point of applying the voltage of Va caused by the address energy recovery operation, the Va pulse width may be wide, and the intensity of the optical waveform caused by the address discharge may be strong as shown in FIG. 5B. That is, the intensity of the optical waveform at the time of the address discharge caused by the hard switching operation may be strong and the discharge success rate may increase.

The successful discharge rate on the first line may influence the successful discharge rate on the next line because of the priming effect when sequentially scanning the next line (the second line). That is, even though using the AERC may delay starting from the second line, may shorten the Va pulse width, and may weaken the intensity of the optical waveform caused by the address discharge as shown in FIG. 6B, if the discharge success rate of the first line is increased by using the hard switching operation because of the priming effect, the successful discharge rate of the second line may also be increased. Consequently, the discharge may be performed well even when the address voltage Va is applied through the AERC.

Because the second line discharges properly, the third line may also properly discharge when the waveform as shown in FIG. 6A is applied. This may lead to a chain of positive results for the fourth to the last lines (like a domino reaction). That is, the successful discharge rate of the first line greatly influences the successful discharge rates of all the lines.

That is, the address voltage of Va may be applied to the first line by the hard switching operation during the address period to thus increase the successful discharge rate and reduce the misfiring that may occur because of the operation by the AERC. Also, the address voltage of Va may be applied to the residual lines (the lines on which some other method is not used) using the AERC, thereby concurrently performing power recovery and reducing power consumption.

Finally, the cells selected in the address period may be discharged by alternately applying the sustain discharge voltage of Vs to the scan electrode Y and the sustain electrode X so as to represent gray scales of the PDP in the sustain period.

Since the waveforms of FIGS. 5 and 6 can be realized by a skilled person in the art through the switching operation of the address driving circuit, no detailed corresponding description will be provided.

While this invention has been described in terms of preferred embodiments, it is to be understood that the invention is not limited to the disclosed embodiments, but, on the contrary, is intended to cover various modifications and equivalent arrangements.

As described, when the first line is scanned in the address period, the address voltage may be applied through a hard switching operation to generate strong light, and hence, the successful discharge rate may be increased, and the successful discharge rates of the subsequent lines may be increased. Further, the address voltage may be applied to the residual lines through AERC to reduce power consumption.

1. A method for driving a plasma display panel including a plurality of first and second electrodes formed on a first substrate, and a plurality of third electrodes formed on a second substrate, approximately adjacent first, second, and third electrodes forming a discharge cell, comprising:
in an address period,
applying a first voltage to a first group of at least one of the first electrodes, and applying a second voltage having a first period to the third electrode while the first voltage is applied; and
applying the first voltage to a second group of the first electrodes exclusive of the first group, and applying the second voltage having a period shorter than the first period to the third electrode while the first voltage is applied.

2. The method of claim 1, wherein the time for applying the second voltage having the first period may be shorter than the time for applying the second voltage having the second period.

3. The method of claim 1, wherein the second voltage applied to the first group is not applied by LC resonance of an energy recovery circuit, and the second voltage applied to the second group is applied by LC resonance of the energy recovery circuit.

4. The method of claim 1, wherein the first voltage is sequentially applied to the first and second groups.

5. The method of claim 1, wherein the first group comprises the first electrode of the first line

6. The method of claim 1, wherein the first group comprises the first line of the display and a line approximately half-way through the display.

7. The method of claim 1, wherein the second group comprises the second line of the display to the last line of the display.

8. The method of claim 1, wherein the second group comprises the second line of the display to the last line of the display exclusive of a line approximately half-way through the display.

9. The method of claim 1, further comprising using a dual scan technique.

10. A plasma display device, comprising:
a first substrate;
a plurality of first and second electrodes on the first substrate;
a plurality of third electrodes on a second substrate facing the first substrate; and
a driving circuit for supplying a driving voltage to the first, second, and third electrodes so as to discharge a discharge cell including the first, second, and third electrodes, and wherein
the driving circuit is adapted to apply a first voltage to a group of at least one of the first electrodes during an address period, to apply a second voltage having a first period to the third electrode while the first voltage is applied, to apply the first voltage to a second group of the first electrodes exclusive of the first group, and to apply a second voltage having a second period shorter than the first period to the third electrode while the first voltage is applied.

11. The plasma display device of claim 10, wherein the time for applying the second voltage having the first period is shorter than the time for applying the second voltage having the second period.

12. The plasma display device of claim 10, wherein the driving circuit is adapted to sequentially apply the first voltage to the first group and then to the second group.

13. The plasma display device of claim 10, wherein the discharge device is adapted to apply the second voltage to the first group without using the LC resonance of an energy recovery circuit, and to apply the second voltage to the second group using LC resonance of the energy recovery circuit.

14. The plasma display device of claim 10, wherein the first group comprises the first electrode of the first line.

15. The plasma display device of claim 10, wherein the first group comprises the first line of the display and a line approximately half-way through the display.

16. The plasma display device of claim 10, wherein the second group comprises the second line of the display to the last line of the display.

17. The plasma display device of claim 10, wherein the second group comprises the second line of the display to the last line of the display exclusive of a line approximately half-way through the display.

18. The plasma display device of claim 10, further comprising using a dual scan technique.

19. The plasma display device of claim 10, wherein the number of total lines is approximately 768.

20. The plasma display device of claim 10, further comprising a high discharge success rate.
